(19) United States
(12) Patent Application Publication
(10) Pub. No.: US 2015/0333227 A1
(43) Pub. Date: Nov. 19, 2015

(54) LIGHT EMITTING DEVICE PACKAGE STRUCTURE AND MANUFACTURING METHOD THEREOF

(71) Applicant: Genesis Photonics Inc., Tainan City (TW)

(72) Inventors: Hao-Chung Lee, Tainan City (TW); Yu-Feng Lin, Tainan City (TW)

(21) Appl. No.: 14/711,798

(22) Filed: May 14, 2015

Related U.S. Application Data
(60) Provisional application No. 62/157,450, filed on May 5, 2015.

(30) Foreign Application Priority Data
May 14, 2014 (TW) 103116987

(51) Int. Cl. H01L 33/38; H01L 33/56; H01L 33/50

(52) U.S. Cl. CPC H01L 33/38; H01L 33/502; H01L 33/56; H01L 2933/0016; H01L 2933/005; H01L 2933/0041

(57) ABSTRACT

A light emitting device package structure and a manufacturing method thereof are provided. The light emitting device package structure includes a light emitting device and a protecting element. The light emitting device has an upper surface and a lower surface opposite to each other, a side surface connecting the upper surface and the lower surface and a first electrode pad and a second electrode pad located on the lower surface and separated from each other. The protecting element encapsulates the side surface of the light emitting device and exposes at least portion of the upper surface, at least portion of a first bottom surface of the first electrode pad and at least portion of a second bottom surface of the second electrode pad.

### CROSS-REFERENCE TO RELATED APPLICATION

This application claims the priority benefit of Taiwan application serial no. 103116987, filed on May 14, 2014, and U.S. provisional application Ser. No. 62/157,450, filed on May 5, 2015. The entirety of each of the above-mentioned patent applications is hereby incorporated by reference herein and made a part of this specification.

### BACKGROUND OF THE INVENTION

1. Field of the Invention

The invention relates to a light emitting device package structure and a manufacturing method thereof, and relates particularly to a light emitting diode package structure and a manufacturing method thereof.

2. Description of Related Art

Generally speaking, in a light emitting diode (LED) package structure typically a light emitting diode (LED) chip is disposed on a carrying base formed in a concave cup shape from ceramic material or metal material, to fix and support the LED diode chip. Then, encapsulation adhesive is used to encapsulate the LED chip, and complete the manufacturing of the LED package structure. Here, an electrode of the LED chip is located above the carrying base and located in the concave cup. However, the carrying base of the concave cup shape has a particular thickness, such that a thickness of the LED package structure may not be reduced efficiently, therefore causing the LED package structure to be unable to meet modern needs of miniaturization.

### SUMMARY OF THE INVENTION

The invention provides a light emitting device package structure, which does not require a conventional carrying support to be adopted, and may have a thinner package thickness and meet miniaturization requirements.

The invention provides a manufacturing method for manufacturing the light emitting device package structure.

A light emitting device package structure of the invention includes a light emitting device and a protecting element. The light emitting device has an upper surface and a lower surface opposite to each other, a side surface connecting the upper surface and the lower surface and a first electrode pad and a second electrode pad located on the lower surface and separated from each other. The protecting element encapsulates the side surface of the light emitting device and exposes the upper surface of the light emitting device. A bottom surface of the protecting element is aligned with a first bottom surface of the first electrode pad and a second bottom surface of the second electrode pad.

The invention provides a manufacturing method of a light emitting device package structure. The manufacturing method includes: disposing a plurality of light emitting devices ranged interval on a substrate, wherein each light emitting device includes a first electrode pad and a second electrode pad located on a lower surface, and the first electrode pad and the second electrode pad are disposed on the substrate; forming a protecting element to encapsulate each light emitting device; removing a part of the protecting element to expose an upper surface of each light emitting device; cutting the protecting element by performing a cutting process to form a plurality of light emitting device package structures separated from each other, wherein each light emitting device package structure includes one light emitting device and the protecting element encapsulating a side surface of the light emitting device and exposing the upper surface; and removing the substrate to expose a bottom surface of the protecting element of each light emitting device package structure and expose a first bottom surface of the first electrode pad and a second bottom surface of the second electrode pad.

The invention further provides a manufacturing method of a light emitting device package structure. The manufacturing method includes: disposing a plurality of light emitting devices ranged interval on a substrate, wherein each light emitting device includes a first electrode pad and a second electrode pad located on a lower surface and separated from each other, and an upper surface of each light emitting device is disposed on the substrate; forming a protecting element to encapsulate each light emitting device; removing a part of the protecting element to expose a first bottom surface of the first electrode pad and a second bottom surface of the second electrode pad of each light emitting device; forming an extension electrode layer to electrically connect to the first electrode pad and the second electrode pad of each light emitting device; and cutting the protecting element and the extension electrode layer by performing a cutting process to form a plurality of light emitting device package structures separated from each other, wherein each light emitting device package structure includes at least one light emitting device, the protecting element at least encapsulating the side surface of the light emitting device, a first extension electrode and a second extension electrode, and the first extension electrode and the second extension electrode are separated from each other and cover a part of a bottom surface of the protecting element.

Based on the above, because the protecting element of the invention encapsulates the side surface of the light emitting device, and the bottom surface of the protecting element is aligned with the first bottom surface of the first electrode pad and the second bottom surface of the second electrode pad of the light emitting device, therefore the light emitting device package structure of the invention does not require a conventional carrying support to support and fix the light emitting device, and may effectively lower the thickness and manufacturing cost of the package. At the same time, the forward light emitting efficiency of the light emitting device can also be effectively increased.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a light emitting device package structure according to an embodiment of the invention.

FIG. 2 is a schematic diagram illustrating a light emitting device package structure according to another embodiment of the invention.

FIG. 3 is a schematic diagram illustrating a light emitting device package structure according to another embodiment of the invention.

FIG. 4 is a schematic diagram illustrating a light emitting device package structure according to another embodiment of the invention.

FIG. 5 is a schematic diagram illustrating a light emitting device package structure according to another embodiment of the invention.

FIG. 6 is a schematic diagram illustrating a light emitting device package structure according to another embodiment of the invention.

FIG. 7 is a schematic diagram illustrating a light emitting device package structure according to another embodiment of the invention.

FIG. 8 is a schematic diagram illustrating a light emitting device package structure according to another embodiment of the invention.

FIG. 9 is a schematic diagram illustrating a light emitting device package structure according to another embodiment of the invention.

FIG. 10A to FIG. 10D are schematic cross-sectional views illustrating a manufacturing method of a light emitting device package structure according to an embodiment of the invention.

FIG. 11A to FIG. 11C are schematic cross-sectional views illustrating partial steps of a manufacturing method of a light emitting device package structure according to another embodiment of the invention.

FIG. 12A to FIG. 12E are schematic cross-sectional views illustrating a manufacturing method of a light emitting device package structure according to another embodiment of the invention.

FIG. 13A to FIG. 13D are schematic cross-sectional views illustrating partial steps of a manufacturing method of a light emitting device package structure according to another embodiment of the invention.

### DESCRIPTION OF THE EMBODIMENTS

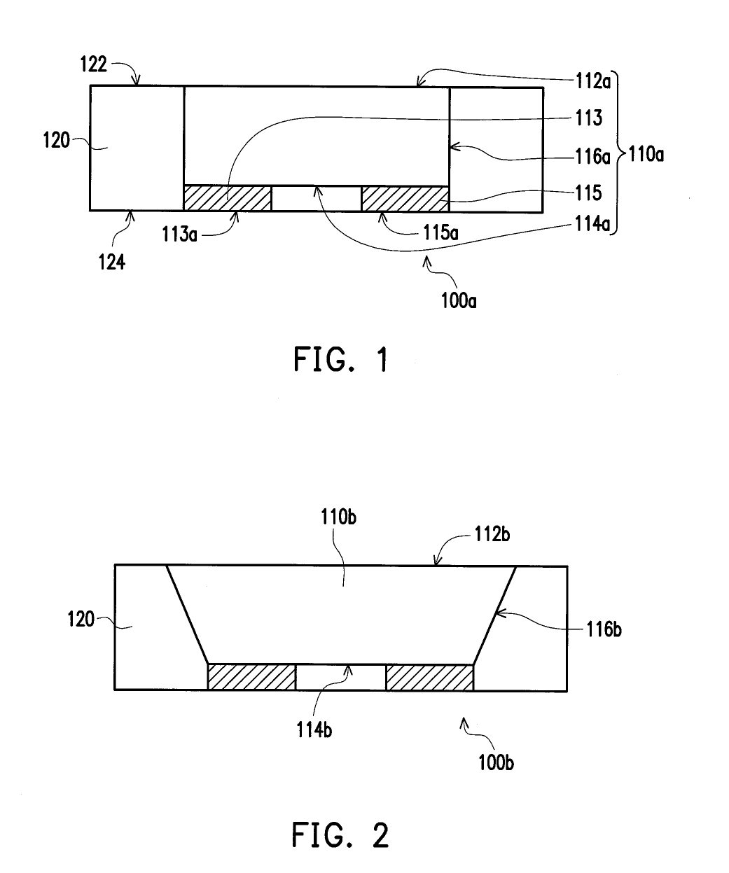

FIG. 1 is a schematic diagram illustrating a light emitting device package structure according to an embodiment of the invention. Referring to FIG. 1, in the present embodiment, a light emitting device package structure 100a includes a light emitting device 110a and a protecting element 120. The light emitting device 110a has an upper surface 112a and a lower surface 114a opposite to each other, a side surface 116a connecting the upper surface 112a and the lower surface 114a and a first electrode pad 113 and a second electrode pad 115 located on the lower surface 114a and separated from each other. The protecting element 120 encapsulates the side surface 116a of the light emitting device 110a and exposes at least portion of the upper surface 112a, at least portion of a first bottom surface 113a of the first electrode pad 113 and at least portion of a second bottom surface 115a of the second electrode pad 115.

More specifically, as shown in FIG. 1, the upper surface 112a of the light emitting device 110a of the present embodiment is aligned with a top surface 122 of the protecting element 120, a bottom surface 124 of the protecting element 120 is aligned with the first bottom surface 113a of the first electrode pad 113 and the second bottom surface 115a of the second electrode 115, and the protecting element 120 also can encapsulate or expose the lower surface 114a of the light emitting device 110a located between the first electrode pad 113 and the second electrode pad 115. In the present embodiment, the side surface 116a of the light emitting device 110a is perpendicular to the upper surface 112a and the lower surface 114a, however the invention is not limited thereto, and the light emitting device 110a, for example, is an LED with a light emitting wavelength (including but not limited thereto) in a range of 315 nanometers to 780 nanometers, and the LED includes but not limited thereto an ultraviolet light LED, a blue light LED, a green light LED, a yellow light LED, an orange light LED or a red light LED.

Preferably, the reflection rate of the protecting element 120 is at least greater than 90%, that is to say, the protecting element 120 of the present embodiment has high reflectivity characteristic, wherein a material of the protecting element 120 is a polymer material doped with high reflective particles, the reflective particle, for example but not limited thereto, titanium dioxide (TiO₂), and the polymer material, for example but not limited thereto, epoxy or silicon. In addition, a material of the first electrode pad 113 and the second electrode pad 115 of the light emitting device 110a of the present embodiment is a metal material or a metal alloy, for example, gold, aluminium, tin, silver, bismuth, indium or a combination thereof, however the invention is not limited thereto.

Because the protecting element 120 of the present embodiment encapsulates the side surface 116a of the light emitting device 110a, and exposes the first bottom surface 113a of the first electrode pad 113 and the second bottom surface 115a of the second electrode pad 115 of the light emitting device 110a, therefore the light emitting device package structure 100a of the present embodiment not only does not require a conventional carrying support to support and fix the light emitting device 110a, may effectively lower the thickness and manufacturing cost of the package. At the same time, the forward light emitting efficiency of the light emitting device 110a may also be effectively increased through the protecting element 120 having high reflectivity.

It should be noted here, the below embodiments utilize the same label and partial contents of the above embodiment, wherein the same labels are adopted to represent same or similar elements and the description of similar technical content is omitted. Reference may be made to the above embodiment for the description of omitted parts and will not be repeated in the below embodiments.

FIG. 2 is a schematic diagram illustrating a light emitting device package structure according, to another embodiment of the invention. Referring to FIG. 1 and

FIG. 2, a light emitting device package structure 100b of the present embodiment and the light emitting device package structure 100a of FIG. 1 are similar. The main difference between the two lies in: a side surface 116b of the light emitting device 110b of the present embodiment is not perpendicular to an upper surface 112b and a lower surface 114b, a surface area of the upper surface 112b of the light emitting device 110b is greater than a surface area of the lower surface 114b. An angle of incidence of the side surface 116b and the lower surface 114b is, for example, between 95 degrees to 150 degree. A contour shape defined by the upper surface 112b, the side surface 116b and the lower surface 114b of the light emitting device 110b of the present embodiment renders a trapezoid, therefore the edge light emitted from the light emitting device 110b occurring may be lowered and the protecting element 120 of high reflectivity may further increase the forward light emitting efficiency of the light emitting device 110b effectively.

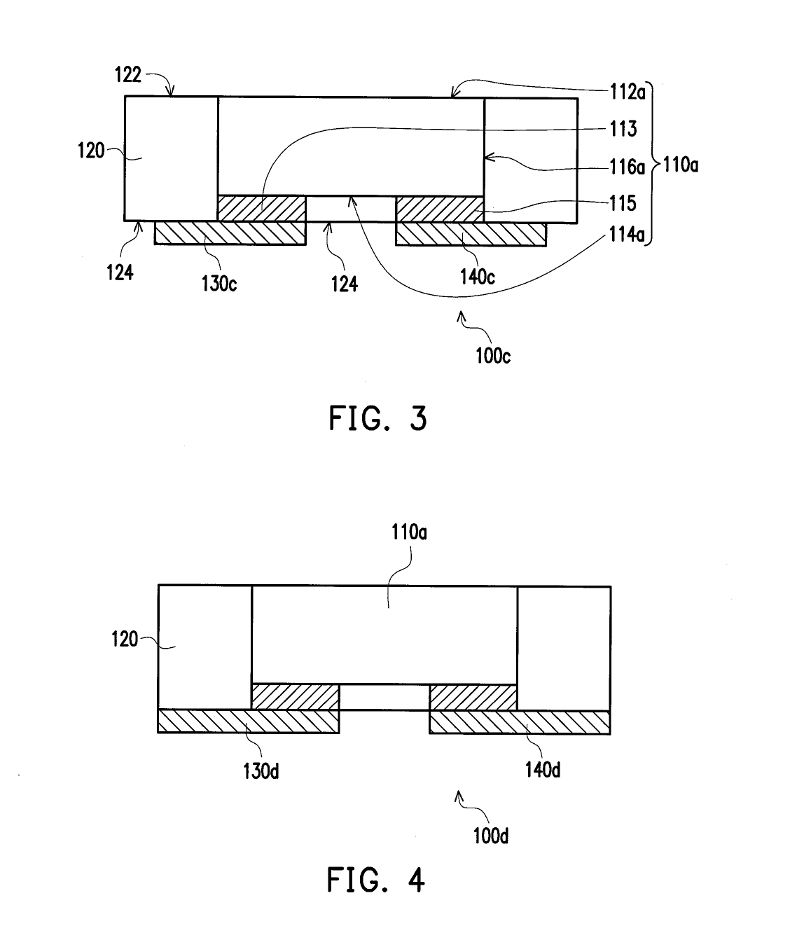

FIG. 3 is a schematic diagram illustrating a light emitting device package structure according to another embodiment of the invention. Referring to FIG. 1 and FIG. 3, a light emitting device package structure 100c of the present embodiment and the light emitting device package structure 100a of FIG. 1 are similar. The main difference between the two lies in: the light emitting device package structure 100c of the present embodiment further includes a first extension electrode 130c and a second extension electrode 140c. The first extension electrode 130c is disposed on the bottom surface 124 of the protecting element 120 and electrically connected to the first electrode pad 113. The second extension electrode 140c is disposed on the bottom surface 124 of the protecting element 120 and directly electrically connected to the second electrode pad 115. The first extension electrode 130c and the second extension electrode 140c are separated from each other and cover a part of the bottom surface 124 of the protecting element 120.

As shown in FIG. 3, a design of the first extension electrode 130c and the second extension electrode 140c of the present embodiment completely overlaps the first electrode pad 113 and the second electrode pad 115, and extends towards an edge of the protecting element 120. Of course, in other embodiments not shown, a design of the first extension electrode and the second extension electrode may also partially overlap the first electrode pad and the second electrode pad, and only a design in which the first extension electrode and the second extension electrode are connected electrically to the first electrode pad and the second electrode pad is the scope namely desired to be protected by the present embodiment. In addition, the first extension electrode 130c and the second extension electrode 140c of the present embodiment are exposed from a part of the bottom surface 124 of the protecting element 120.

In the present embodiment, a material of the first extension electrode 130c and the second extension electrode 140c may be respectively the same or different with the first pad electrode 113 and the second electrode pad 115 of the light emitting device 110a. When the material of the first extension electrode 130c and the second extension electrode 140c are respectively the same as the first electrode pad 113 and the second electrode pad 115 of the light emitting device 110a, a seamless connection may be made between the first extension electrode 130c and the first electrode pad 113, namely an integrally formed structure, and a seamless connection may be made between the second extension electrode 140c and the second electrode pad 115, namely an integrally formed structure. When the material of the first extension electrode 130c and the second extension electrode 140c are respectively different than the first electrode pad 113 and the second electrode pad 115 of the light emitting device 110a, the material of the first extension electrode 130c and the second extension electrode 140c may, for example, be silver, gold, bismuth, tin, indium or an alloy thereof of the above materials.

Because the light emitting device package structure 100c of the present embodiment has the first extension electrode 130c and the second extension electrode 140c respectively connected electrically with the first pad electrode 113 and the second electrode pad 115 of the light emitting device 110a, therefore an electrode contact area of the light emitting device package structure 100c may be effectively increased, to facilitate performing the subsequent assembly of the light emitting device package structure 100c with other outside circuits, and may increase the alignment accuracy and the assembly efficiency. For example, an area of the first extension electrode 130c is greater than an area of the first electrode pad 113 and an area of the second extension electrode 140c is greater than an area of the second electrode pad 115.

FIG. 4 is a schematic diagram illustrating a light emitting device package structure according to another embodiment of the invention. Referring to FIG. 3 and FIG. 4, a light emitting device package structure 100d of the present embodiment and the light emitting device package structure 100c of FIG. 3 are similar. The main difference between the two lies in: an edge of a first extension electrode 130d and an edge of the second extension electrode 140d of the present embodiment are aligned with the edge of the protecting element 120.

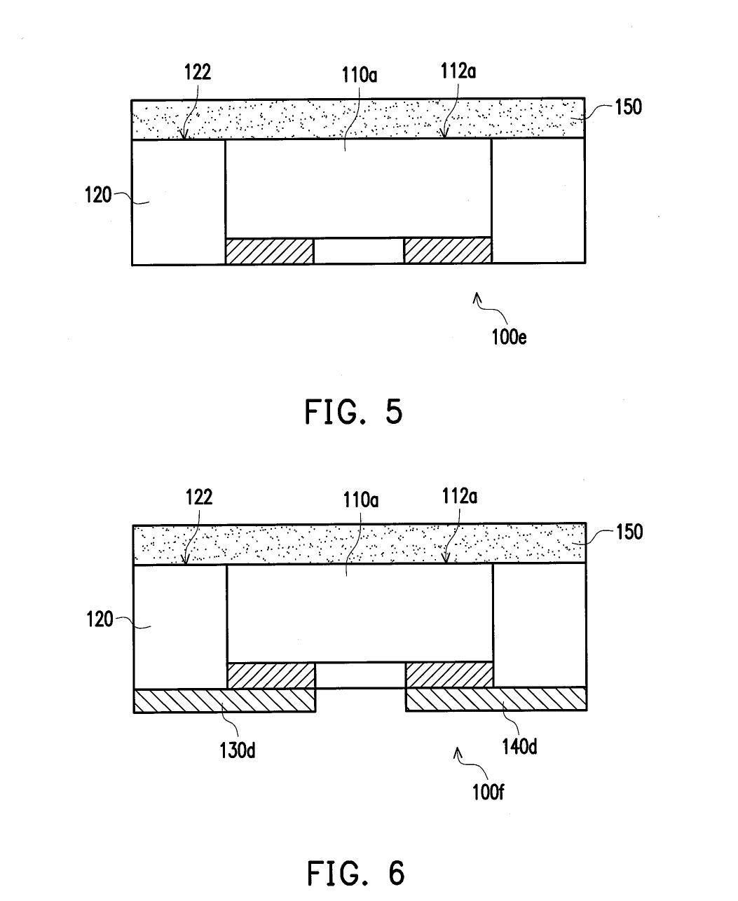

FIG. 5 is a schematic diagram illustrating a light emitting device package structure according to another embodiment of the invention. Referring to FIG. 1 and FIG. 5, a light emitting device package structure 100e of the present embodiment and the light emitting device package structure 100a of FIG. 1 are similar. The main difference between the two lies in: the light emitting device package structure 100e of the present embodiment further includes an encapsulation adhesive layer 150, wherein the encapsulation adhesive layer 150 is disposed on the upper surface 112a of the light emitting device 110a, to increase light extraction efficiency and improve the light pattern. The encapsulation adhesive layer 150 may also extend onto at least portion of the upper surface 122 of the protecting element 120, such that an edge of the encapsulation adhesive layer 150 can be aligned with the edge of the protecting element 120. In addition, at least one wavelength converting material may be doped in the encapsulation adhesive layer 150, wherein the wavelength converting material is used to convert the wavelengths of at least part of the light beam emitted by the light emitting device 110a into other wavelengths of light beam, and a material of the wavelength converting material includes fluorescent material, phosphorescent material, dyes, quantum dot material or a combination thereof. A particle sizes of the wavelength converting material, for example, is between 3 micrometers to 50 micrometers. In addition, oxides having high scattering ability may be doped in the encapsulation adhesive layer 150, for example, Titanium dioxide (TiO₂) or Silicon dioxide (SiO₂), to increase light emitting efficiency.

In one present embodiment of the invention, the light emitting device includes but not limited thereto a ultraviolet light emitting device, a blue light emitting device, a green light emitting device a yellow light emitting device, an orange light emitting device or a red light emitting device, and the wavelength converting material includes but not limited thereto a red wavelength converting material, an orange wavelength converting material, an orange-yellow wavelength converting material, a yellow wavelength converting material, a yellow-green wavelength converting material, a green wavelength converting material or a combination thereof, and is used to convert the wavelengths of part or all of the light beam emitted by the light emitting device. Wavelength converted light and unconverted light wavelength light after mixing, the light emitting device package structure emits a light with a dominant wavelength at a specific wavelength range, its light color such as, but not limited to red, orange, orange-yellow, amber, yellow, yellow-green or green, or a white light with a specific correlated color temperature, the correlated color temperature range, for example, between 2500K to 7000K, but not limited thereto.

FIG. 6 is a schematic diagram illustrating a light emitting device package structure according to another embodiment of the invention. Referring to FIG. 6 and FIG. 4, a light emitting device package structure 100f of the present embodiment and the light emitting device package structure 100d of FIG. 4 are similar. The main difference between the two lies in: the light emitting device package structure 100f of the present embodiment further includes the encapsulation adhesive layer 150, wherein the encapsulation adhesive layer 150 is disposed on the upper surface 112a of the light emitting device 110a, to increase light extraction efficiency and improve the light pattern. The encapsulation adhesive layer 150 may also extend onto at least portion of the upper surface 122 of the protecting element 120, and the edge of the encapsulation adhesive layer 150 can be aligned with the edge of the protecting element 120. In addition, at least one wavelength converting material may be doped in the encapsulation adhesive layer 150, wherein the wavelength converting material is used to convert the wavelengths of at least part of the light beam emitted by the light emitting device 110a into other wavelengths of light beam, and a material of the wavelength converting material includes fluorescent material, phosphorescent material, dyes, quantum dot material or a combination thereof. A particle sizes of the wavelength converting material, for example, is between 3 micrometers to 50 micrometers. In addition, oxides having high scattering ability may be doped in the encapsulation adhesive layer 150, for example, Titanium dioxide (TiO₂) or Silicon dioxide (SiO₂), to increase light emitting efficiency.

It should be noted, in the embodiments of FIG. 4 and FIG. 6, the edge of the first extension electrode 130d and the edge of the second extension electrode 140d are aligned with the edge of the protecting element 120. This type of design not only may expand a contact area of the electrode, but in the manufacturing process, the protecting element 120 may encapsulate a plurality of light emitting devices 110a ranged interval at the same time, and after forming a patterned metal layer so as to respectively form the first extension electrode 130d and the second extension electrode 140d at the same time, then cutting is performed such that the edge of the first extension electrode 130d and the edge of the second extension electrode 140d of each light emitting device package structure 100f are aligned with the edge of the protecting element 120. In this way, manufacturing time may be saved.

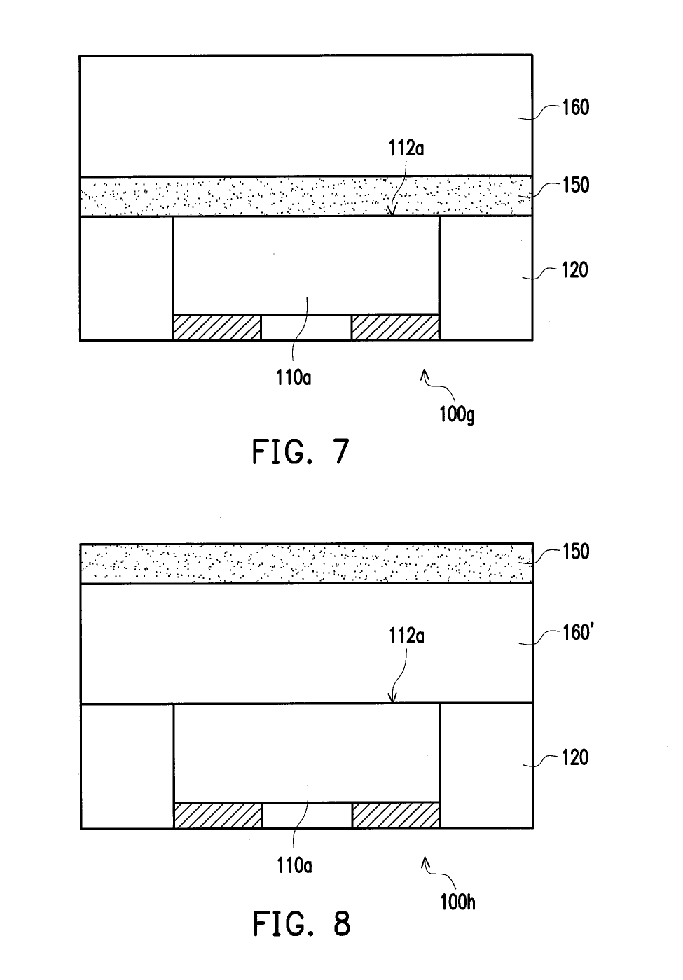

FIG. 7 is a schematic diagram illustrating a light emitting device package structure according to another embodiment of the invention. With reference to FIG. 7 and FIG. 5, a light emitting device package structure 100g of the present embodiment is similar to the light emitting device package structure 100e of FIG. 5, and a main difference is that: the light emitting device package structure 100g of the present embodiment further includes a translucent layer 160 disposed on the encapsulation adhesive layer 150, wherein a transmittance of the translucent layer 160, for example, is greater than 50%. In the present embodiment, a material of the translucent layer 160 is glass, ceramics, resins, acrylic, silicone or etc., for example, for guiding the light generated by the light emitting device 110a to the outside to effectively increase a light flux and a light extraction rate of the light emitting device package structure 100g and for effectively protecting the light emitting device 110a from influence of external moisture and oxygen.

FIG. 8 is a schematic diagram illustrating a light emitting device package structure according to another embodiment of the invention. With reference to FIG. 8 and FIG. 7, a light emitting device package structure 100h of the present embodiment is similar to the light emitting device package structure 100 g of FIG. 7, and a main difference is that: a translucent layer 160′ of the light emitting device package structure 100h of the present embodiment is disposed between the upper surface 112a of the light emitting device 110a and the encapsulation adhesive layer 150.

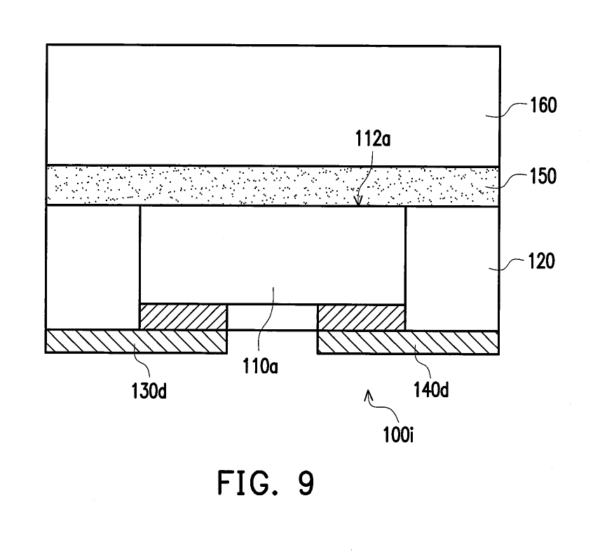

FIG. 9 is a schematic diagram illustrating a light emitting device package structure according to another embodiment of the invention. With reference to FIG. 9 and FIG. 6, a light emitting device package structure 100i of the present embodiment is similar to the light emitting device package structure 100f of FIG. 6, and a main difference is that: the light emitting device package structure 100i of the present embodiment further includes a translucent layer 160 disposed on the encapsulation adhesive layer 150, wherein a transmittance of the translucent layer 160, for example, is greater than 50%. In the present embodiment, a material of the translucent layer 160 is glass, ceramics, resins, acrylic, silicone or etc., for example, for guiding the light generated by the light emitting device 110a to the outside to effectively increase a light flux and a light extraction rate of the light emitting device package structure 100i and for effectively protecting the light emitting device 110a from influence of external moisture and oxygen.

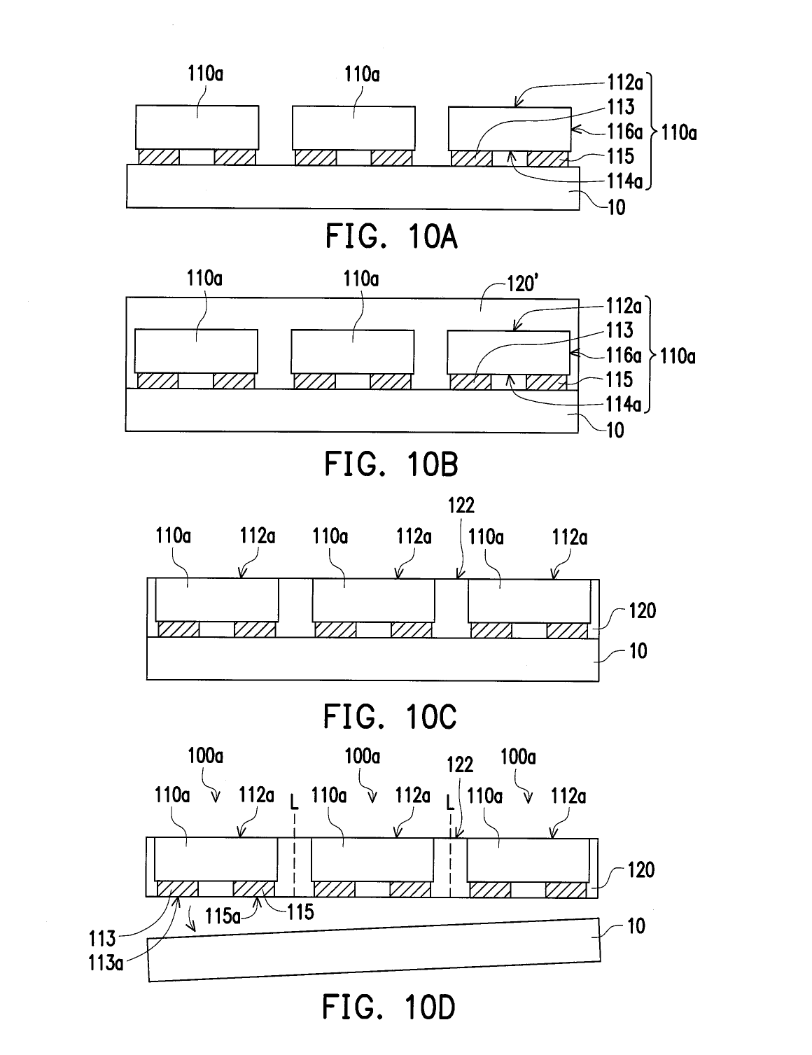

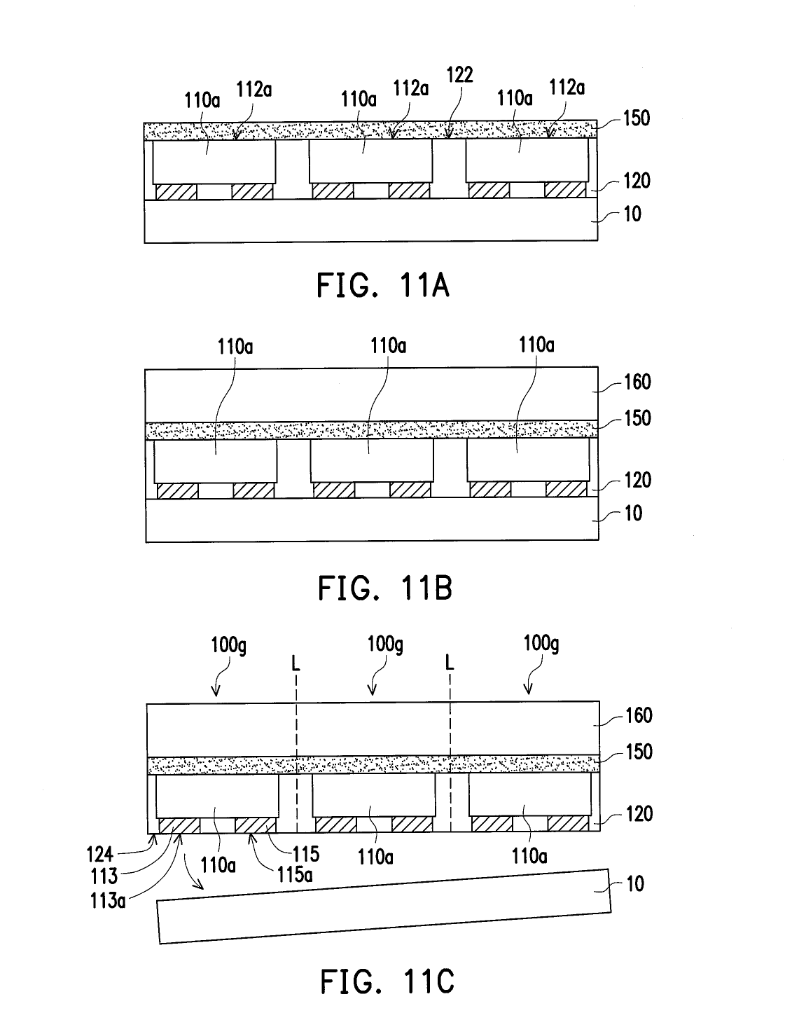

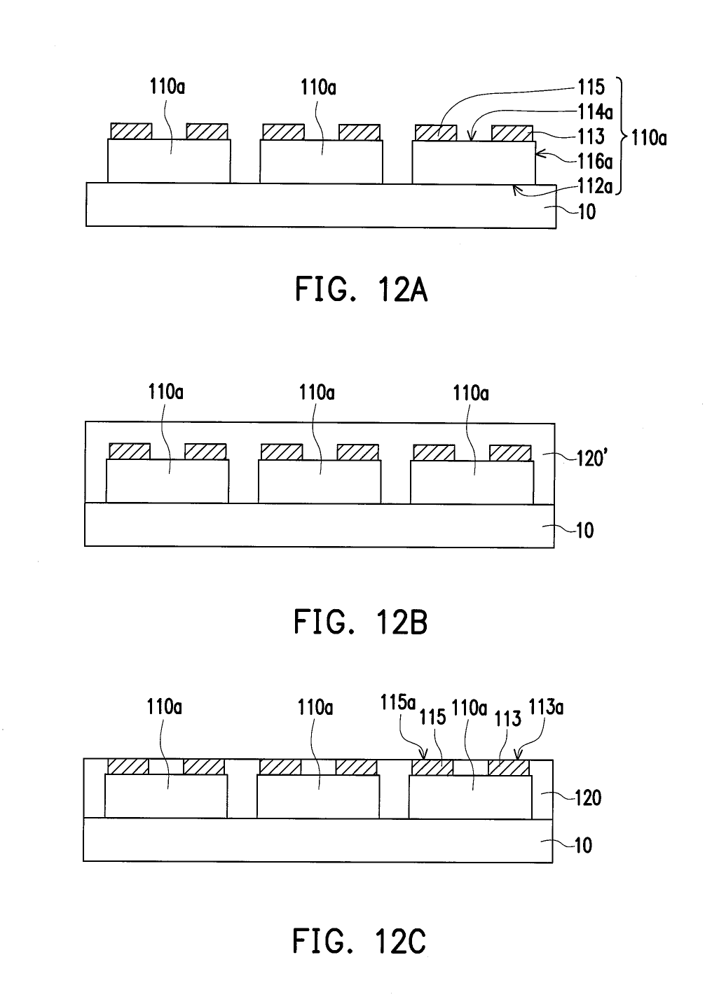

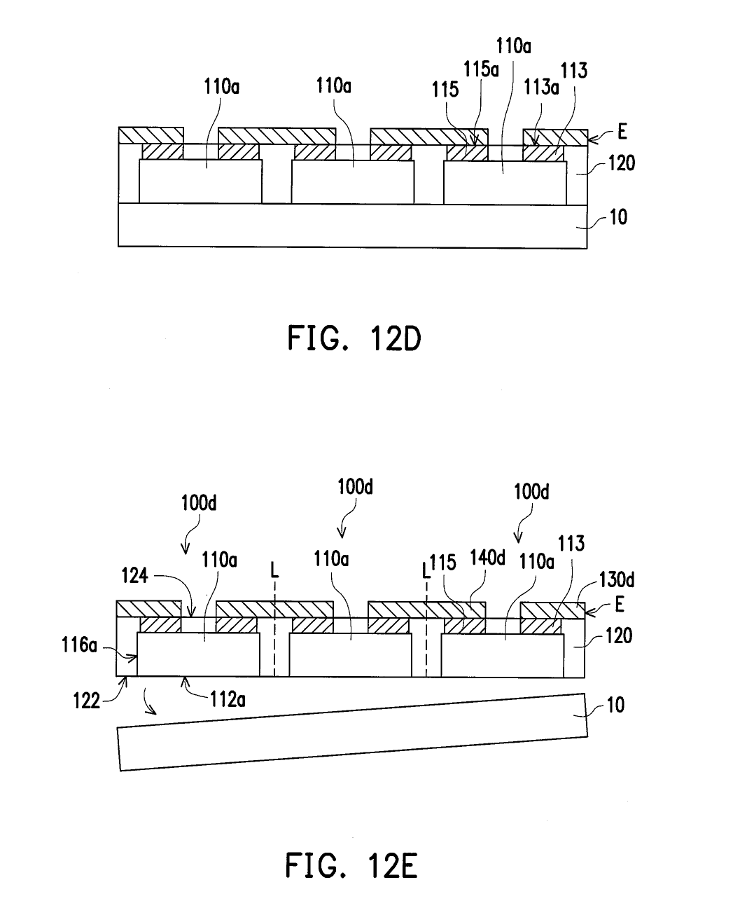

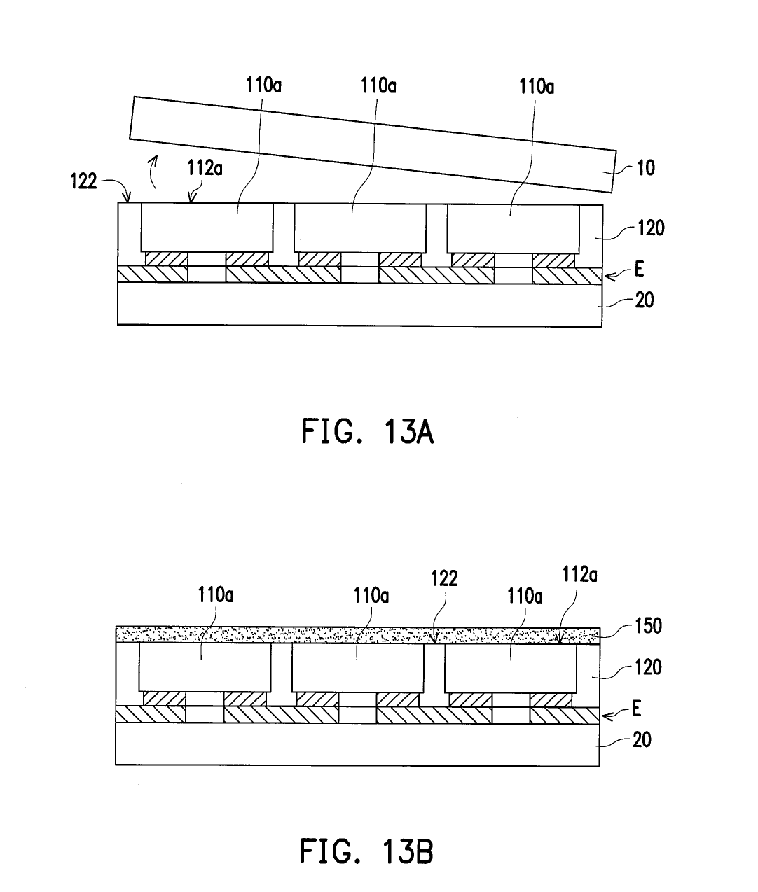

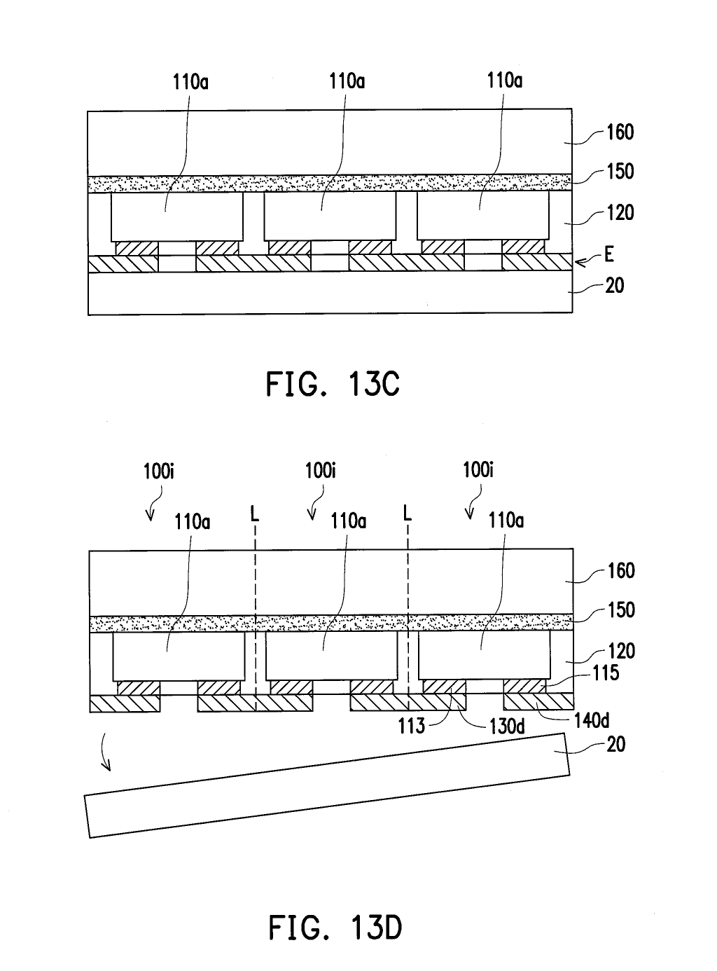

In the following embodiments, the light emitting device package structures 100a, 100g, 100d, and 100i of the invention are taken as examples for specifically describing a manufacturing method of the light emitting device package structure of the invention respectively with reference to FIG. 10A to FIG. 10D, FIG. 11A to FIG. 11C, FIG. 12A to FIG. 12E, and FIG. 13A to FIG. 13D. FIG. 10A to FIG. 10D are schematic cross-sectional views illustrating a manufacturing method of a light emitting device package structure according to an embodiment of the invention. With reference to FIG. 10A, first, a plurality of light emitting devices 110a are disposed on a substrate 10, wherein each light emitting device 110a has an upper surface 112a and a lower surface 114a opposite to each other, a side surface 116a connecting the upper surface 112a and the lower surface 114a, and a first electrode pad 113 and a second electrode pad 115 located on the lower surface 114a and separated from each other. The first electrode pad 113 and the second electrode pad 115 of each light emitting device 110a are disposed on the substrate 10. In other words, a light emitting surface of the light emitting device 110a, i.e. the upper surface 112a, is relatively away from the substrate 10. In the present embodiment, a material of the rigid substrate 10 is stainless steel, ceramics, or other non-conductive materials, for example. The light emitting device 110a, for example, is an LED with a light emitting wavelength (including but not limited thereto) in a range of 315 nanometers to 780 nanometers, and the LED includes but not limited thereto an ultraviolet light LED, a blue light LED, a green light LED, a yellow light LED, an orange light LED or a red light LED.

Then, with reference to FIG. 10B, a protecting element 120′ is formed on the substrate 10, wherein the protecting element 120′ encapsulates each light emitting device 110a. In other words, the protecting element 120′ completely and directly covers the upper surface 112a, the lower surface 114a, and the side surface 116a of the light emitting device 110a and fills a gap between the first electrode pad 113 and the second electrode pad 115. Here, a reflection rate of the protecting element 120′ is at least greater than 90%. That is to say, the protecting element 120′ of the present embodiment has a high reflectivity characteristic, wherein a material of the protecting element 120′ is a polymer material doped with high reflective particles, the reflective particle, for example but not limited thereto, titanium dioxide (TiO₂), and the polymer material, for example but not limited thereto, epoxy or silicon.

Then, with reference to FIG. 10C, a part of the protecting element 120′ is removed to form a protecting element 120, wherein the protecting element 120 exposes at least portion of the upper surface 112a of each light emitting device 110a. Moreover, the upper surface 112a of each light emitting device 110a can be aligned with a top surface 122 of the protecting element 120. Here, a method of removing a part of the protecting element 120′ is a grinding method or a polishing method, for example.

Thereafter, with reference to FIG. 10D, a cutting process is performed to cut the protecting element 120 along a cutting line L so as to form a plurality of light emitting device package structures 100a separated from each other, wherein each light emitting device package structure 100a includes at least one light emitting device 110a and the protecting element 120 encapsulating the side surface 116a of the light emitting device 110a and exposing at least portion of the upper surface 112a.

Finally, with reference to FIG. 10D, the substrate 10 is removed to expose a bottom surface 124 of the protecting element 120 of each light emitting device package structure 100a, at least portion of a first bottom surface 113a of the first electrode pad 113 and at least portion of a second bottom surface 115a of the second electrode pad 115.

FIG. 11A to FIG. 11C are schematic cross-sectional views illustrating partial steps of a manufacturing method of a light emitting device package structure according to another embodiment of the invention. The manufacturing method of the light emitting device package structure of the present embodiment is similar to the manufacturing method of the light emitting device package structure of FIG. 10A to FIG. 10D, and a main difference is that: between the steps of FIG. 10C and FIG. 10D, namely, after removing a part of the protecting element 120′ and before performing the cutting process, with reference to FIG. 11A, an encapsulation adhesive layer 150 is formed on the light emitting device 110a and the protecting element 120 to increase the light extraction rate and improve the light pattern. Here, the encapsulation adhesive layer 150 covers the upper surface 112a of the light emitting device 110a and the top surface 122 of the protecting element 120, and at least one wavelength converting material can be doped in the encapsulation adhesive layer 150. The relevant illustration of the wavelength converting material can be referred to the aforementioned embodiments. In addition, an oxide having high scattering ability, such as titanium dioxide (TiO₂) or silicon dioxide (SiO₂) may be doped in the encapsulation adhesive layer 150 to increase the light emitting efficiency.

Then, with reference to FIG. 11B, a translucent layer 160 is formed on the light emitting device 110a and the protecting element 120, wherein the translucent layer 160 is located on the encapsulation adhesive layer 150 and covers the encapsulation adhesive layer 150. For example, a transmittance of the translucent layer 160 is greater than 50%. In the present embodiment, a material of the translucent layer 160 is glass, ceramics, resins, acrylic, silicone or etc., for example, for guiding the light generated by the light emitting device 110a to the outside to effectively increase a light flux and a light extraction rate of the light emitting device package structure 100g formed in the subsequent process and for effectively protecting the light emitting device 110a from influence of external moisture and oxygen.

Thereafter, with reference to FIG. 11C, a cutting process is performed to cut the translucent layer 160, the encapsulation adhesive layer 150, and the protecting element 120 along a cutting line L so as to form a plurality of light emitting device package structures 100g separated from each other. Finally, with reference to FIG. 11C, the substrate 10 is removed to expose a bottom surface 124 of the protecting element 120 of each light emitting device package structure 100g, wherein the bottom surface 124 of the protecting element 120 of each light emitting device package structure 100g exposes to at least portion of a first bottom surface 113a of the first electrode pad 113 and at least portion of a second bottom surface 115a of the second electrode pad 115.

FIG. 12A to FIG. 12E are schematic cross-sectional views illustrating a manufacturing method of a light emitting device package structure according to another embodiment of the invention. First, with reference to FIG. 12A, the manufacturing method of the light emitting device package structure of the present embodiment is similar to the manufacturing method of the light emitting device package structure of FIG. 10A to FIG. 10D, and a main difference is that: with reference to FIG. 12A, the light emitting device 110a of the present embodiment is not contact with the substrate 10 through the first electrode pad 113 and the second electrode pad 115, but through the upper surface 112a.

Then, with reference to FIG. 12B, a protecting element 120′ is formed on the substrate 10, wherein the protecting element encapsulates each light emitting device 110a.

Next, with reference to FIG. 12C, a part of the protecting element 120′ is removed to form a protecting element 120, wherein the protecting element 120 exposes at least portion of a first bottom surface 113a of the first electrode pad 113 and at least portion of a second bottom surface 115a of the second electrode pad 115 of each light emitting device 110a.

Then, with reference to FIG. 12D, a patterned metal layer is formed as an extension electrode layer E which is located on the first bottom surface 113a of the first electrode pad 113 and the second bottom surface 115a of the second electrode pad 115 of each light emitting device 110a. Here, a method of forming the extension electrode layer E is a vapor deposition method, a sputtering method, a plating method, a chemical plating method or a mask etching method, for example.

Thereafter, with reference to FIG. 12E, a cutting process is performed to cut the extension electrode layer E and the protecting element 120 along a cutting line so as to form a plurality of light emitting device package structures 100d separated from each other, wherein each light emitting device package structure 100d includes at least one light emitting device 110a, the protecting element 120 at least encapsulating the side surface 116a of the light emitting device 110a, a first extension electrode 130d in direct contact with the first electrode pad 113, and a second extension electrode 140d in direct contact with the second electrode pad 115. The first extension electrode 130d and the second extension electrode 140d are separated from each other and expose a part of the bottom surface 124 of the protecting element 120. At the moment, the area of the first extension electrode 130d can be greater than the area of the first electrode pad 113 and the area of the second extension electrode 140d is greater than the area of the second electrode pad 115. An edge of the first extension electrode 130d and an edge of the second extension electrode 140d are aligned with an edge of the protecting element 120.

Finally, with reference to FIG. 12E, the substrate 10 is removed to expose the top surface 122 of the protecting element 120 and the upper surface 112a of the light emitting device 110a of each light emitting device package structure 100d, wherein the top surface 122 of the protecting element 120 of each light emitting device package structure 100d is aligned with the upper surface 112a of the light emitting device 110a. In another embodiment, the cutting process can be performed after removing the substrate 10.

FIG. 13A to FIG. 13D are schematic cross-sectional views illustrating partial steps of a manufacturing method of a light emitting device package structure according to another embodiment of the invention. The manufacturing method of the light emitting device package structure of the present embodiment is similar to the manufacturing method of the light emitting device package structure of FIG. 12A to FIG. 12E, and a main difference is that: between the steps of FIG. 12D and FIG. 12E, namely, after forming the extension electrode layer E and before performing the cutting process, with reference to FIG. 13A, another substrate 20 is provided and disposed on extension electrode layer E. Here, a material of the another substrate 20 is stainless steel, ceramics, or other non-conductive materials, for example. Then, with reference to FIG. 13A again, after providing the another substrate 20, the substrate 10 is removed to expose the top surface 122 of the protecting element 120 and the upper surface 112a of the light emitting device 110a, wherein the upper surface 112a of each light emitting device 110a is aligned with the top surface 122 of the protecting element 120.

Next, with reference to FIG. 13B, an encapsulation adhesive layer 150 is formed on the light emitting device 110a and the protecting element 120 to increase the light extraction rate and improve the light pattern. Here, the encapsulation adhesive layer 150 covers the upper surface 112a of the light emitting device 110a and the top surface 122 of the protecting element 120, and at least one wavelength converting material can be doped in the encapsulation adhesive layer 150. The relevant illustration of the wavelength converting material can be referred to the aforementioned embodiments. In addition, an oxide having high scattering ability, such as titanium dioxide (TiO₂) or silicon dioxide (SiO₂) may be doped in the encapsulation adhesive layer 150 to increase the light emitting efficiency.

Then, with reference to FIG. 13C, a translucent layer 160 is formed on the light emitting device 110a and the protecting element 120, wherein the translucent layer 160 is located on the encapsulation adhesive layer 150 and covers the encapsulation adhesive layer 150. For example, a transmittance of the translucent layer 160 is greater than 50%. Here, a material of the translucent layer 160 is glass, ceramics, resins acrylic, silicone or etc, for example, for guiding the light generated by the light emitting device 110a to the outside to effectively increase a light flux and a light extraction rate of the light emitting device package structure 100i formed in the subsequent process and for effectively protecting the light emitting device 110a from influence of external moisture and oxygen.

Thereafter, with reference to FIG. 13D, a cutting process is performed to cut the translucent layer 160, the encapsulation adhesive layer 150, the protecting element 120 and extension electrode layer E along a cutting line L so as to form a plurality of light emitting device package structures 100i separated from each other. Finally, with reference to FIG. 13D, the another rigid substrate 20 is removed to expose the first extension electrode 130d and the second extension electrode 140d of each light emitting device package structure 100. In another embodiment, the cutting process can be performed after removing the another substrate 20.

In summary, because the protecting element of the invention encapsulates the side surface of the light emitting device, and the bottom surface of the protecting element expose the first bottom surface of the first electrode pad and the second bottom surface of the second electrode pad of the light emitting device, therefore the light emitting device package structure of the invention does not require a conventional carrying support to support and fix the light emitting device, and may effectively lower the thickness and manufacturing cost of the package. At the same time, the forward light emitting efficiency of the light emitting device may also be effectively increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting device package structure, comprising:
a light emitting device, having an upper surface and a lower surface opposite to each other, a side surface connecting the upper surface and the lower surface and a first electrode pad and a second electrode pad located on the lower surface and separated from each other; and
a protecting element, encapsulating the side surface of the light emitting device and exposing at least portion of the upper surface of the light emitting device, at least portion of a first bottom surface of the first electrode pad and at least portion of a second bottom surface of the second electrode pad.

2. The light emitting device package structure as claimed in claim 1, wherein the upper surface of the light emitting device is aligned with a top surface of the protecting element.

3. The light emitting device package structure as claimed in claim 1, further comprising:
a first extension electrode, disposed on the bottom surface of the protecting element, and electrically connected to the first electrode pad; and
a second extension electrode, disposed on the bottom surface of the protecting element, and electrically connected to the second electrode pad, wherein the first extension electrode and the second extension electrode are separated from each other and are exposed from at least a part of the bottom surface of the protecting element.

4. The light emitting device package structure as claimed in claim 3, wherein an area of the first extension electrode is greater than an area of the first electrode pad, and an area of the second extension electrode is greater than an area of the second electrode pad.

5. The light emitting device package structure as claimed in claim 3, wherein an edge of the first extension electrode and an edge of the second extension electrode are aligned with an edge of the protecting element.

6. The light emitting device package structure as claimed in claim 1, wherein the light emitting device is a light emitting diode chip with a light emitting wavelength in a range of 315 nanometers to 780 nanometers.

7. The light emitting device package structure as claimed in claim 1, wherein a reflection rate of the protecting element is at least greater than 90%.

8. The light emitting device package structure as claimed in claim 1, further comprising:
an encapsulation adhesive layer, disposed on the upper surface of the light emitting device.

9. The light emitting device package structure as claimed in claim 8, wherein the encapsulation adhesive layer covers at least portion of a top surface of the protecting element.

10. The light emitting device package structure as claimed in claim 8, wherein at least one wavelength converting material is doped in the encapsulation adhesive layer.

11. The light emitting device package structure as claimed in claim 10, further comprising:
a translucent layer disposed on the upper surface of the light emitting device.

12. The light emitting device package structure as claimed in claim 11, wherein a transmittance of the translucent layer is greater than 50%.

13. The light emitting device package structure as claimed in claim 1, wherein an angle of incidence of the side surface and the bottom surface of the light emitting device is between 95 degrees to 150 degrees.

14. A manufacturing method of a light emitting device package structure, the manufacturing method comprising:
disposing a plurality of light emitting devices ranged interval on a substrate, wherein each light emitting device comprises a first electrode pad and a second electrode pad located on a lower surface and separated from each other, and the first electrode pad and the second electrode pad are disposed on the substrate;
forming a protecting element to encapsulate each light emitting device;
removing a part of the protecting element to expose an upper surface of each light emitting device;
cutting the protecting element by performing a cutting process to form a plurality of light emitting device package structures separated from each other, wherein each light emitting device package structure comprises at least one light emitting device and the protecting element encapsulating a side surface of the light emitting device and exposing the upper surface; and
removing the substrate to expose a bottom surface of the protecting element of each light emitting device package structure, and expose a first bottom surface of the first electrode pad and a second bottom surface of the second electrode pad.

15. The manufacturing method as claimed in claim 14, wherein a reflection rate of the protecting element is at least greater than 90%.

16. The manufacturing method as claimed in claim 14, wherein the upper surface of each light emitting device is aligned with a top surface of the protecting element after removing the part of the protecting element.

17. The manufacturing method as claimed in claim 14, wherein a method of removing the part of the protecting element comprises a grinding method or a polishing method.

18. The manufacturing method as claimed in claim 14, further comprising:
forming an encapsulation adhesive layer on the light emitting devices and the protecting element after removing the part of the protecting element and before performing the cutting process, wherein the encapsulation adhesive layer covers the upper surfaces of the light emitting devices and the top surface of the protecting element.

19. The manufacturing method as claimed in claim 18, wherein at least one wavelength converting material is doped in the encapsulation adhesive layer.

20. The manufacturing method as claimed in claim 19, further comprising: forming a translucent layer on the light emitting devices and the protecting element, wherein the encapsulation adhesive layer is located between the translucent layer and the light emitting devices, or the translucent layer is located between the light emitting devices and the encapsulation adhesive layer.

21. The manufacturing method as claimed in claim 20, wherein a transmittance of the translucent layer is greater than 50%.

22. The manufacturing method as claimed in claim 14, wherein each light emitting device is a light emitting diode chip with a light emitting wavelength in a range of 315 nanometers to 780 nanometers.

23. A manufacturing method of a light emitting device package structure, the manufacturing method comprising:
disposing a plurality of light emitting devices ranged interval on a substrate, wherein each light emitting device comprises a first electrode pad and a second electrode pad located on a lower surface and separated from each other, and an upper surface of each light emitting device is disposed on the substrate;
forming a protecting element to encapsulate each light emitting device;
removing a part of the protecting element to expose a first bottom surface of the first electrode pad and a second bottom surface of the second electrode pad of each light emitting device;
forming an extension electrode layer to electrically connect to the first electrode pad and the second electrode pad of each light emitting device; and
cutting the protecting element and the extension electrode layer by performing a cutting process to form a plurality of light emitting device package structures separated from each other, wherein each light emitting device package structure comprises at least one light emitting device, the protecting element at least encapsulating the side surface of the light emitting device, a first extension electrode and a second extension electrode, and the first extension electrode and the second extension electrode are separated from each other and cover at least a part of a bottom surface of the protecting element.

24. The manufacturing method as claimed in claim 23, wherein an area of the first extension electrode is greater than an area of the first electrode pad, and an area of the second extension electrode is greater than an area of the second electrode pad.

25. The manufacturing method as claimed in claim 23, wherein an edge of the first extension electrode and an edge of the second extension electrode are aligned with an edge of the protecting element.

26. The manufacturing method as claimed in claim 23, wherein a reflection rate of the protecting element is at least greater than 90%.

27. The manufacturing method as claimed in claim 23, wherein a method of removing the part of the protecting element comprises a grinding method or a polishing method.

28. The manufacturing method as claimed in claim 23, further comprising:
removing the substrate to expose a top surface of the protecting element and the upper surfaces of the light emitting devices after performing the cutting process.

29. The manufacturing method as claimed in claim 23, further comprising:
providing another substrate after forming the extension electrode layer and before performing the cutting process, wherein the extension electrode layer is disposed one the another substrate; and
removing the substrate to expose the top surface of the protecting element and the upper surface of each of the light emitting devices

30. The manufacturing method as claimed in claim 29, further comprising:
forming an encapsulation adhesive layer on the light emitting devices and the protecting element after removing the substrate and before performing the cutting process, wherein the encapsulation adhesive layer covers the upper surface of each of the light emitting devices and the top surface of the protecting element.

31. The manufacturing method as claimed in claim 30, wherein at least one wavelength converting material is doped in the encapsulation adhesive layer.

32. The manufacturing method as claimed in claim 30, further comprising:
forming a translucent layer on the light emitting devices and the protecting element before performing the cutting process.

33. The manufacturing method as claimed in claim 32, wherein a transmittance of the translucent layer is greater than 50%.

34. The manufacturing method as claimed in claim 32, further comprising:
removing the another substrate to expose the first extension electrode and the second extension electrode of each light emitting device package structure after forming the encapsulation adhesive layer and the translucent layer on the light emitting devices and the protecting element.
